(19) United States
(12) Patent Application Publication
(10) Pub. No.: US 2025/0132249 A1
(43) Pub. Date: Apr. 24, 2025

(54) SEMICONDUCTOR DEVICE AND INTERCONNECTION STRUCTURE IN SEMICONDUCTOR DEVICE

(71) Applicant: Samsung Electronics Co., Ltd., Suwon-si (KR)

(72) Inventors: Muryeong KUK, Suwon-si (KR); Dosun LEE, Suwon-si (KR); Seongheum CHOI, Suwon-si (KR); Hongkeun PARK, Suwon-si (KR); Giwoong SHIM, Suwon-si (KR)

(73) Assignee: Samsung Electronics Co., Ltd., Suwon-si (KR)

(21) Appl. No.: 18/761,886

(22) Filed: Jul. 2, 2024

(30) Foreign Application Priority Data
Sep. 7, 2023 (KR) 10-2023-0118775

(51) Int. Cl. H01L 23/522; H01L 23/528; H01L 23/532

(52) U.S. Cl. CPC H01L 23/5228; H01L 23/5283; H01L 23/53266

(57) ABSTRACT

An interconnection structure may include a first insulating interlayer on a substrate, a first metal pattern on the substrate and passing through the first insulating interlayer, a seed metal layer pattern surrounding a portion of a sidewall of the first metal pattern and a bottom of the first metal pattern, and a second metal pattern. The second metal pattern may directly contact an uppermost surface of the seed metal layer pattern, the upper sidewall of the first metal pattern, and the upper surface of the first metal pattern. An upper sidewall and an upper surface of the first metal pattern may be exposed by the seed metal layer pattern. The second metal pattern may fill at least a recess between the first insulating interlayer and the first metal pattern.

### CROSS-REFERENCE TO RELATED APPLICATION

This application claims priority under 35 USC § 119 to Korean Patent Application No. 10-2023-0118775, filed on Sep. 7, 2023, in the Korean Intellectual Property Office (KIPO), the contents of which are incorporated by reference herein in their entirety.

### BACKGROUND

Various example embodiments relate to a semiconductor device and an interconnection structure in the semiconductor device. Particularly, various example embodiments relate to a semiconductor device including an interconnection structure having low resistance.

The semiconductor device may include the interconnection structure being electrically connected to circuit patterns. The interconnection structure may include contact structures. As a diameter of each of the contact structures decreases, a resistance of each of the contact structures may be increased. Accordingly, a resistance of the interconnection structure may be increased.

### SUMMARY

Various example embodiments provide an interconnection structure having low resistance.

Various example embodiments provide a semiconductor device including the interconnection structure.

According to some example embodiments, an interconnection structure may be in a semiconductor device. The interconnection structure may include a substrate; a first insulating interlayer on the substrate; a first metal pattern on the substrate and passing through the first insulating interlayer; a seed metal layer pattern surrounding a portion of a sidewall of the first metal pattern, a bottom of the first metal pattern, an upper sidewall of the first metal pattern and an upper surface of the first metal pattern, the upper sidewall of the first metal pattern and the upper surface of the first metal pattern being exposed by the seed metal layer pattern; and a second metal pattern directly contacting an uppermost surface of the seed metal layer pattern, the upper sidewall of the first metal pattern, and the upper surface of the first metal pattern. The second metal pattern may fill at least a recess between the first insulating interlayer and the first metal pattern.

According to some example embodiments, an interconnection structure may be in a semiconductor device. The interconnection structure may include a substrate; a first insulating interlayer on the substrate, and the first insulating interlayer including a first hole exposing a surface of the substrate; a seed metal layer pattern conformally on a sidewall of the first hole and a bottom of the first hole, the seed metal layer pattern having a first resistance; a first metal pattern on the seed metal layer pattern and filling the first hole, an upper sidewall of the first metal pattern positioned above an uppermost surface of the seed metal layer pattern, the first metal pattern being exposed by the seed metal layer, the first metal pattern having a second resistance, and the second resistance being lower than the first resistance; a second insulating interlayer on the first insulating interlayer; and a second metal pattern passing through the second insulating interlayer. The second metal pattern may directly contact the uppermost surface of the seed metal layer pattern, the upper sidewall of the first metal pattern, and an upper surface of the first metal pattern.

According to some example embodiments, a semiconductor device may include a substrate; a nanosheet structure on the substrate, the nanosheet structure including a nanosheet stack and a semiconductor pattern on sidewalls of the nanosheet stack, and the nanosheet stack including silicon patterns spaced apart in a vertical direction, the vertical direction being perpendicular to a surface of the substrate; a gate structure on the nanosheet stack, the gate structure covering the nanosheet stack; a first insulating interlayer covering sidewalls of the gate structure and on the semiconductor pattern, the first insulating interlayer including a first hole exposing the semiconductor pattern; a seed metal layer pattern conformally on a sidewall of the first hole and a bottom of the first hole, the seed metal layer pattern having a first resistance; a first metal pattern on the seed metal layer pattern and filling the first hole, an upper sidewall of the first metal pattern positioned above an uppermost surface of the seed metal layer pattern, the uppermost surface of the seed metal layer pattern being exposed by the seed metal layer pattern, the first metal pattern having a second resistance, and the second resistance being lower than the first resistance; a second insulating interlayer on the first insulating interlayer; a second metal pattern passing through the second insulating interlayer, the second metal pattern directly contacting the uppermost surface of the seed metal layer pattern, the upper sidewall of the first metal pattern, and an upper surface of the first metal pattern.

According to various example embodiments, the interconnection structure may have a low resistance

### BRIEF DESCRIPTION OF THE DRAWINGS

Various example embodiments will be more clearly understood from the following detailed description taken in conjunction with the accompanying drawings. FIGS. 1 to 26 represent various non-limiting, example embodiments as described herein.

FIG. 1 is a cross-sectional view of illustrating an interconnection structure according to example embodiments;

FIG. 2 is a cross-sectional view of illustrating an interconnection structure according to example embodiments;

FIG. 3 is a cross-sectional view of an interconnection structure according to example embodiments;

FIG. 4 is a cross-sectional view of an interconnection structure according to example embodiments;

FIGS. 5 to 13 are cross-sectional views for illustrating a method of manufacturing an interconnection structure according to example embodiments;

FIG. 14 is a cross-sectional view illustrating an interconnection structure according to an example embodiment;

FIG. 15 is a cross-sectional view illustrating an interconnection structure according to an example embodiment;

FIG. 16 is a cross-sectional view illustrating an interconnection structure according to an example embodiment;

FIG. 17 is a cross-sectional view illustrating an interconnection structure according to an example embodiment;

FIGS. 18 and 19 are cross-sectional views illustrating a method for manufacturing an interconnection structure according to an example embodiment;

FIG. 20 is a cross-sectional view illustrating an interconnection structure according to an example embodiment;

FIG. 21 is a cross-sectional view illustrating an interconnection structure according to an example embodiment;

FIG. 22 is a cross-sectional view illustrating an interconnection structure according to an example embodiment;

FIG. 23 is a cross-sectional view illustrating an interconnection structure according to an example embodiment;

FIGS. 24 and 25 are cross-sectional views illustrating a method for manufacturing an interconnection structure according to an example embodiment; and

FIG. 26 is a cross-sectional view illustrating a semiconductor device including an interconnection structure according to an example embodiment.

### DETAILED DESCRIPTION

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%. While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%). The notion that elements are “substantially the same” may indicate that the element may be completely the same and may also indicate that the elements may be determined to be the same in consideration of errors or deviations occurring during a process.

Hereinafter, various example embodiments will be described in detail with reference to the accompanying drawings.

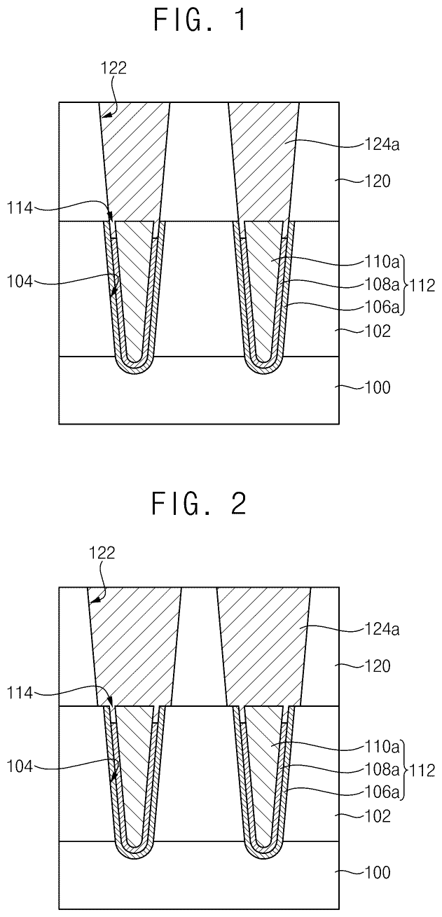

FIG. 1 is a cross-sectional view of illustrating an interconnection structure according to example embodiments. FIG. 2 is a cross-sectional view of illustrating an interconnection structure according to example embodiments.

Referring to FIG. 1, a first insulating interlayer 102 may be formed on a substrate 100. The first insulating interlayer 102 may include, e.g., silicon oxide or silicon nitride.

A first hole 104 may pass through the first insulating interlayer 102, and may exposes a surface of the substrate 100. In example embodiments, the surface of the substrate 100 may be exposed by a bottom of the first hole 104. In some example embodiments, a conductive pattern (not shown) including a metal silicide may be formed on the substrate 100, and a surface of the conductive pattern may be exposed by the bottom of the first hole 104.

In example embodiments, the first hole 104 may have a circular shape or an oval shape, in a plan view.

In example embodiments, a width (e.g., a diameter) of the first hole 104 may be gradually decreased from an upper portion to a bottom thereof. Accordingly, a sidewall of the first hole 104 may be inclined so that the width of the first hole 104 may become narrower from the upper portion to the bottom thereof. The upper portion of the first hole 104 may have a first width.

A first contact structure 112 may be disposed in the first hole 104. The first contact structure 112 may include a barrier pattern 106a, a seed metal layer pattern 108a, and a first metal pattern 110a.

The barrier pattern 106a may be formed conformally on the sidewall and the bottom of the first hole 104. In example embodiments, the barrier pattern 106a may have a uniform thickness from the sidewall and the bottom of the first hole 104. The barrier pattern 106a may include, e.g., titanium, titanium nitride, tantalum, tantalum nitride, or tungsten nitride, etc.

The seed metal layer pattern 108a may be formed on the barrier pattern 106a, and may be conformally on the sidewall and the bottom of the first hole 104. In example embodiments, the seed metal layer pattern 108a may have a deposition thickness of in range of about 3 Å to about 20 Å.

The first metal pattern 110a may be formed on the seed metal layer pattern 108a, and may fill the first hole 104. A volume of the first metal pattern 110a may be greater than a volume of the seed metal layer pattern 108a and a volume of the barrier pattern 106a. The first metal pattern 110a may pass through the first insulating interlayer 102.

The barrier pattern 106a may be disposed between the bottom of the seed metal layer pattern 108a and the surface of the substrate 100. The barrier pattern 106a may surround an outer surface of the seed metal layer pattern 108a.

The seed metal layer pattern 108a may be a seed pattern for forming the first metal pattern 110a. A resistance of the first metal pattern 110a may be lower than a resistance of the seed metal layer pattern 108a.

The seed metal layer pattern 108a and the first metal pattern 110a may include the same metal.

In example embodiments, the seed metal layer pattern 108a and the first metal pattern 110a may include tungsten. In this case, the seed metal layer pattern 108a may be an amorphous tungsten pattern including at least boron. For example, the seed metal layer pattern 108a may be an amorphous tungsten pattern including boron or an amorphous tungsten pattern including boron and silicon.

The first metal pattern 110a may be a bulk tungsten pattern. The first metal pattern 110a may not include boron and/or silicon.

In some example embodiments, the seed metal layer pattern 108a and the first metal pattern 110a may include aluminum, copper, ruthenium, cobalt, nickel, palladium, platinum, silver, or gold, etc.

In the first contact structure 112, an uppermost surface of the seed metal layer pattern 108a may not be coplanar with uppermost surfaces of the barrier pattern 106a and the first metal pattern 110a. The uppermost surfaces of the barrier pattern 106a and the first metal pattern 110a may be coplanar with an upper surface of the first insulating interlayer 102.

In the first contact structure 112, the uppermost surface of the seed metal layer pattern 108a may be lower than the uppermost surfaces of the barrier pattern 106a and the first metal pattern 110a. A recess 114 may be disposed between the barrier pattern 106a and the first metal pattern 110a above the uppermost surface of the seed metal layer pattern 108a.

An upper outer wall of the first metal pattern 110a may be exposed by the recess 114. An upper sidewall of the first metal pattern 110a positioned above the uppermost surface of the seed metal layer pattern 108a may not be surrounded by the seed metal layer pattern 108a, and may be exposed by the seed metal layer pattern 108a. Additionally, an upper sidewall of the barrier pattern 106a may also be exposed by the seed metal layer pattern 108a.

A second insulating interlayer 120 may be on the first insulating interlayer 102 and the first contact structure 112. The second insulating interlayer 120 may include, e.g., silicon oxide or silicon nitride.

In example embodiments, the first and second insulating interlayers 102 and 120 may have different insulation materials. Additionally, the first insulating interlayer 102 may have an etch selectivity with respect to the second insulating interlayer 120. For example, the first insulating interlayer 102 may include silicon nitride, and the second insulating interlayer 120 may include silicon oxide. In this case, the first and second insulating interlayers 102 and 120 have a high etch selectivity to each other. Therefore, an etch stop layer may not be formed between the first and second insulating interlayers 102 and 120.

A second hole 122 may pass through the second insulating interlayer 120. At least the upper surface and the upper sidewall of the first metal pattern 110a and the uppermost surface of the seed metal layer pattern 108a may be exposed by a bottom of the second hole 122. The recess 114 may be exposed by the bottom of the second hole 122.

A second metal pattern 124a may be disposed in the second hole 122. The second metal pattern 124a may pass through the second insulating interlayer 120.

In example embodiments, the second metal pattern 124a may be formed by a selective chemical vapor deposition process in which a layer is selectively and upward deposited from the bottom of the second hole 122. The second metal pattern 124a may be formed by a bottom up fill growth.

A metal may be grown along grains of the upper surfaces of the first metal pattern 110a and the seed metal layer pattern 108a to form the second metal pattern 124a having a single grain.

In example embodiments, the second metal pattern 124a may include tungsten. However, the second metal pattern 124a may not be limited to tungsten. For example, the second metal pattern 124a may include aluminum, copper, ruthenium, cobalt, nickel, palladium, platinum, silver, or gold, etc.

The second metal pattern 124a may directly contact the upper sidewall and the upper surface of the first metal pattern 110a exposed by the bottom of the second hole 122. As the second metal pattern 124a may contact the upper sidewall and the upper surface of the first metal pattern 110a, a contact area between the second metal pattern 124a and the first contact structure 112 may be increased. Accordingly, a contact resistance between the second metal pattern 124a and the first contact structure 112 may be decreased.

A bottom of the second metal pattern 124a may include a first bottom contacting the upper surface of the first metal pattern 110a and a second bottom contacting the uppermost surface of the seed metal layer pattern 108a. The first and second bottoms may not be coplanar with each other. A vertical depth from the upper surface of the second metal pattern 124a to the first bottom of the second metal pattern 124a may be less than a vertical depth from the upper surface of the second metal pattern 124a to the second bottom of the second metal pattern 124a.

The second metal pattern 124a may fill the second hole 122 and the recess 114 of the bottom of the second hole 122. Accordingly, the second metal pattern 124a may directly contact the uppermost surface of the seed metal layer pattern 108a exposed by the bottom of the second hole 122 and the upper sidewall of the barrier pattern 106a.

A width of the lower surface of the second metal pattern 124a may be greater than a width of the upper surface of the first metal pattern 110a in the first contact structure 112.

In example embodiments, as shown in FIG. 1, the width of the lower surface of the second metal pattern 124a may be substantially the same or less than an upper width of the first contact structure 112.

In some example embodiments, as shown in FIG. 2, the width of the lower surface of the second metal pattern 124a may be greater than the upper width of the first contact structure 112. In this case, the lower surface of the second metal pattern 124a may be on the upper surfaces of the first contact structure 112 and the first insulating interlayer 102 adjacent to the first contact structure 112. An interconnection structure shown in FIG. 2 may be the same as the interconnection structure shown in FIG. 1, except for the width of the lower surface of the second metal pattern 124a.

A shape of the second metal pattern 124a may be determined by a shape of the second hole 122. In example embodiments, the second hole 122 may have an opening shape, and thus the second metal pattern 124a may be a via contact plug contacting an underlying metal. In some example embodiments, the second hole 122 may have a trench shape extending in one direction, and the second metal pattern 124a may be a conductive line pattern.

As shown in FIGS. 1 and 2, the second metal pattern 124a may contact the upper surface and the upper sidewall of the first metal pattern 110a having the low resistance, so that the contact area between the second metal pattern 124a and the first metal pattern 110a may be increased. Therefore, the resistance of the interconnection structure including the first contact structure 112 and the second metal pattern 124a may be decreased.

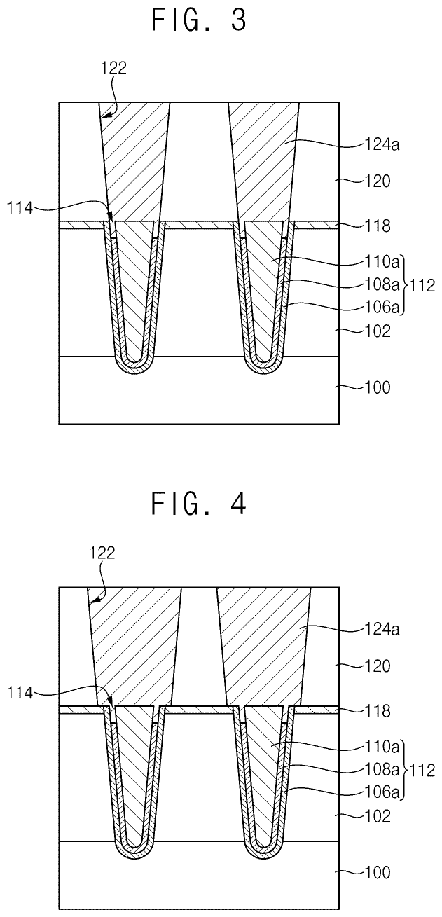

FIG. 3 is a cross-sectional view of an interconnection structure according to example embodiments. FIG. 4 is a cross-sectional view of an interconnection structure according to example embodiments.

Referring to FIG. 3, the first insulating interlayer 102 and an etch stop layer 118 may be sequentially stacked on the substrate 100.

In example embodiments, the first insulating interlayer 102 may include silicon oxide, and the etch stop layer 118 may include silicon nitride.

The first contact structure 112 may pass through the etch stop layer 118 and the first insulating interlayer 102. The first contact structure 112 may include the barrier pattern 106a, the seed metal layer pattern 108a, and the first metal pattern 110a.

In the first contact structure 112, an uppermost surface of the seed metal layer pattern 108a may not be coplanar with uppermost surfaces of the barrier pattern 106a and the first metal pattern 110a. The uppermost surfaces of the barrier pattern 106a and the first metal pattern 110a may be coplanar with an upper surface of the etch stop layer 118.

In the first contact structure 112, the uppermost surface of the seed metal layer pattern 108a may be lower than uppermost surfaces of the barrier pattern 106a and the first metal pattern 110a. An upper portion of the first metal pattern 110a may protrude from the uppermost of the seed metal layer pattern 108a. The recess 114 may be disposed between the barrier pattern 106a and the first metal pattern 110a above the uppermost surface of the seed metal layer pattern 108a.

The second insulating interlayer 120 may be on the etch stop layer 118 and the first contact structure 112. The second insulating interlayer 120 may include a material having a high etch selectivity with respect to the etch stop layer 118. The second insulating interlayer 120 may include, e.g., silicon oxide.

The second metal pattern 124a may pass through the second insulating interlayer 120, and may contact the first contact structure 112. The second metal pattern 124a may directly contact the upper sidewall and the upper surface of the first metal pattern 110a, the uppermost surface of the seed metal layer pattern 108a, and an upper sidewall of the barrier pattern 106a exposed by a bottom of the second hole 122. The second metal pattern 124a may fill the second hole 122 and the recess 114.

In example embodiments, as shown in FIG. 3, a width of the lower surface of the second metal pattern 124a may be substantially the same as or less than the upper width of the first contact structure 112.

In some example embodiments, as shown in FIG. 4, the width of the lower surface of the second metal pattern 124a may be greater than the upper width of the first contact structure 112. The lower surface of the second metal pattern 124a may be disposed on the upper surfaces of the first contact structure 112 and the etch stop layer 118 adjacent the first contact structure 112. An interconnection structure shown in FIG. 4 may be the same as an interconnection structure shown in FIG. 3, except for the width of the lower surface of the second metal pattern 124a.

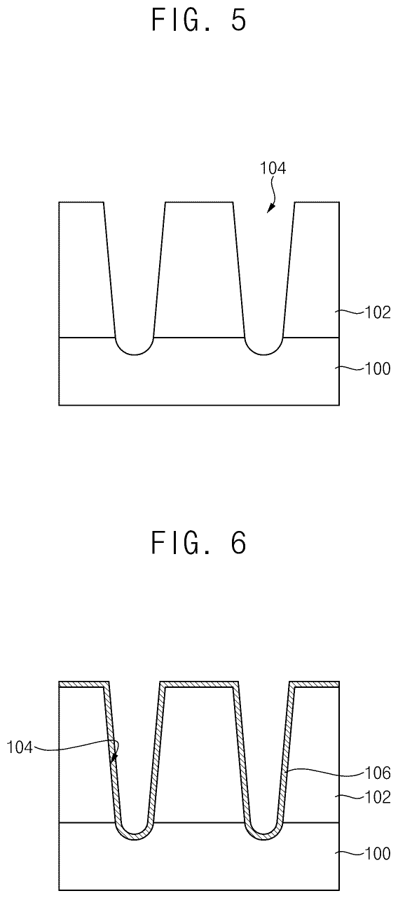

FIGS. 5 to 13 are cross-sectional views for illustrating a method of manufacturing an interconnection structure according to example embodiments.

Referring to FIG. 5, a first insulating interlayer 102 may be formed on a substrate 100.

The substrate 100 may include silicon, germanium, silicon-germanium, or a group III-V compound such as GaP, GaAs, or GaSb. In some example embodiments, the substrate 100 may be a Silicon On Insulator (SOI) substrate or a Germanium On Insulator (GOI) substrate.

The first insulating interlayer 102 may include, e.g., silicon oxide or silicon nitride.

In example embodiments, an etch stop layer 118 (referred to FIG. 3) may be further formed on the first insulating interlayer 102. In this case, an interconnection structure shown in FIG. 3 or FIG. 4 may be formed by subsequent processes.

A portion of the first insulating interlayer 102 may be etched to form first holes 104. Processes for forming the first holes 104 may include a photo process and an etching process. The etching process may include a dry etching process.

In some example embodiments, example embodiments, when the etch stop layer is formed on the first insulating interlayer 102, portions of the etch stop layer and the first insulating interlayer 102 may be etched to form first holes 104.

Referring to FIG. 6, a barrier layer 106 may be conformally formed on the sidewalls and the bottom of the first holes 104 and an upper surface of the first insulating interlayer 102. The barrier layer 106 may be formed to have a uniform thickness on the sidewalls and the bottom of the first holes 104 and the upper surface of the first insulating interlayer 102. The barrier layer 106 may be an adhesion layer to improve an adhesive property of a conductive material subsequently formed thereon. Further, the barrier layer 106 may be provided to limit and/or prevent diffusion of the conductive material.

In example embodiments, a metal silicide or the substrate 100 including a semiconductor material may be exposed by the bottom of the first hole 104. The barrier layer 106 may be the adhesion layer to improve the adhesive property between the substrate and the conductive material subsequently formed or between the metal silicide and the conductive material subsequently formed.

The barrier layer 106 may include, e.g., titanium, titanium nitride, tantalum, tantalum nitride, etc. The barrier layer 106 may be formed by, e.g., a chemical vapor deposition process or an atomic layer deposition process.

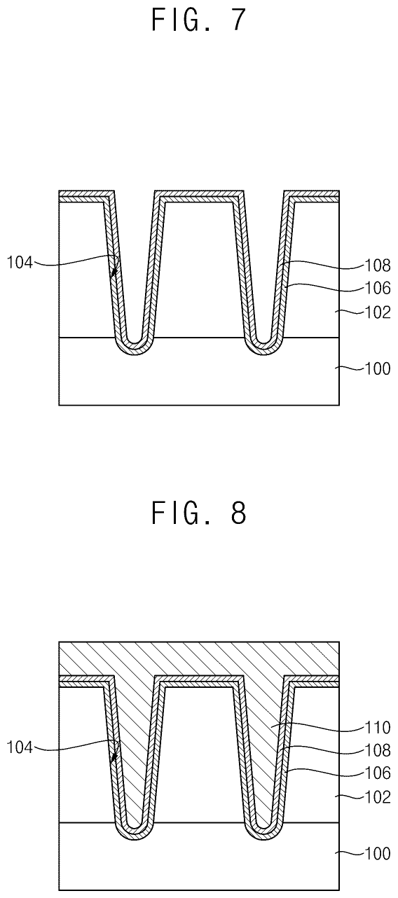

Referring to FIG. 7, a seed metal layer 108 may be conformally formed on the barrier layer 106. The seed metal layer 108 may be a seed layer for deposition of a first metal layer 110 (refer to FIG. 8) subsequently formed. In example embodiments, the seed metal layer 108 may include a metal included in the first metal layer 110.

The seed metal layer 108 on an upper surface of the barrier layer 106 may have an adhesion property better than an adhesion property of the first metal layer 110 on the upper surface of the barrier layer 106. The seed metal layer 108 may have a resistance higher than a resistance of the first metal layer 110. The seed metal layer 108 may serve as a metal nucleation layer. The first metal layer 110 formed on the seed metal layer 108 may have a large grain size by the seed metal layer 108, so that a resistance of a first contact structure may be decreased.

In example embodiments, the seed metal layer 108 and the first metal layer 110 may be formed in situ.

In example embodiments, the seed metal layer 108 may be formed to have a deposition thickness of about 3 Å to about 20 Å. In the deposition process, it is not easy to form the seed metal layer 108 having a thickness less than 3 Å. When the seed metal layer 108 has a thickness greater than 20 Å, the resistance of the first contact structure may be increased.

Referring to FIG. 8, the first metal layer 110 may be formed on the seed metal layer 108 to fill the first hole 104.

The first metal layer 110 may be formed by a chemical vapor deposition process using the seed metal layer 108 as a seed. The first metal layer 110 may have a resistance lower than a resistance of the seed metal layer 108. When the first metal layer 110 contacts an upper surface of the seed metal layer 108, the first metal layer 110 may have good deposition characteristic and filling characteristic compared to when the first metal layer 110 directly contact on the barrier layer. Accordingly, seams or voids inside the first hole 104 may be decreased.

In example embodiments, the seed metal layer 108 and the first metal layer 110 may include tungsten. Hereinafter, the seed metal layer 108 and the first metal layer 110 including tungsten may be described.

The seed metal layer 108 may include an amorphous tungsten layer including at least boron. For example, the seed metal layer 108 may be an amorphous tungsten layer including boron. Alternatively, the seed metal layer 108 may be an amorphous tungsten layer including boron and silicon. The first metal layer 110 may include a bulk tungsten layer.

In example embodiments, the seed metal layer 108 may be formed by a chemical vapor deposition process or an atomic layer deposition using B₂H₆ and WF₆ as deposition sources.

In some example embodiments, the seed metal layer 108 may include a first tungsten layer formed by a chemical vapor deposition process or an atomic layer deposition using SiH₄ and WF₆ as deposition sources, and a second tungsten layer formed by a chemical vapor deposition using B₂H₆ and WF₆ as deposition sources. The deposition sources for forming the seed metal layer 108 may include a gas including boron and a gas including a metal.

In example embodiments, the first metal layer 110 may be formed by a chemical vapor deposition process using H₂ and WF₆ as deposition sources. In this case, the first metal layer 110 may be grown on the seed metal layer 108, and may have a resistance lower than a resistance of the seed metal layer 108.

However, the metal included in the seed metal layer 108 and the first metal layer 110 may not be limited to the tungsten. For example, the seed metal layer 108 and the first metal layer 110 may include aluminum, copper, ruthenium, cobalt, nickel, palladium, platinum, silver, gold, etc.

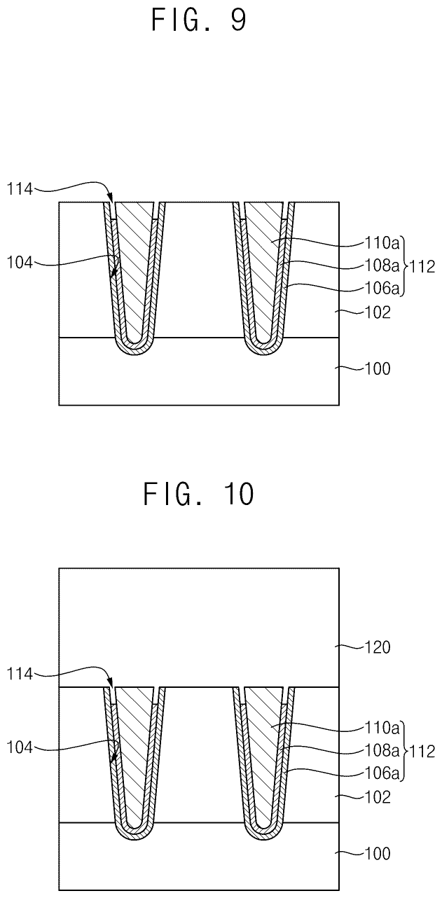

Referring to FIG. 9, the barrier layer 106, the seed metal layer 108, and the first metal layer 110 may be planarized until an upper surface of the first insulating interlayer 102 is exposed to form a first contact structure 112 filling each of the first holes. The first contact structure 112 may include a barrier pattern 106a, a seed metal layer pattern 108a, and a first metal pattern 110a. The planarization process may include, e.g., a chemical mechanical polishing process.

When the planarization process is performed, the seed metal layer 108 may not be polished or removed to have an uppermost surface on the same plane as uppermost surfaces of the barrier layer 106 and the first metal layer 110. When the planarization process is performed, the seed metal layer 108 may be removed faster than the barrier layer 106 and the first metal layer 110.

Accordingly, in the first contact structure 112, the uppermost surface of the seed metal layer pattern 108a may be lower than the uppermost surfaces of the barrier pattern 106a and the first metal pattern 110a. A recess 114 may be disposed between the barrier pattern 106a and the first metal pattern 110a above the uppermost surface of the seed metal layer pattern 108a.

In the first contact structure 112, an upper outer wall of the first metal pattern 110a may be exposed by the recess 114. Additionally, an upper sidewall of the barrier pattern 106a may also be exposed by the recess 114.

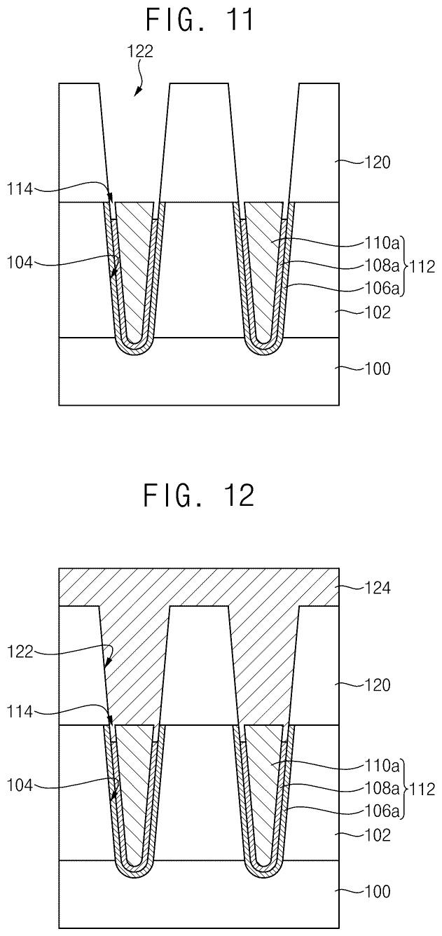

Referring to FIG. 10, a second insulating interlayer 120 may be formed on the first insulating interlayer 102 and the first contact structure 112. The second insulating interlayer 120 may include silicon oxide or silicon nitride.

Referring to FIG. 11, a portion of the second insulating interlayer 120 may be etched to form second holes 122. The process for forming the second holes 122 may include a photo process and an etching process. The etching process may include a dry etching process.

At least an upper surface and an upper sidewall of the first metal pattern 110a and the uppermost surface of the seed metal layer pattern 108a may be exposed by a bottom of the second hole 122. The recess 114 may be exposed by the bottom of the second hole 122.

In example embodiments, upper surfaces of the first metal pattern 110a and the seed metal layer pattern 108a may be exposed by the bottom of the second hole 122. Accordingly, a lower width of the second hole 122 may be substantially the same as or less than an upper width of the first contact structure 112. In this case, an interconnection structure shown in FIG. 1 or FIG. 3 may be formed by subsequent processes.

In some example embodiments, an entire upper surface of the first contact structure 112 and the upper surface of the first insulating interlayer 102 adjacent to the first contact structure 112 may be exposed by the bottom of the second hole 122. Accordingly, the lower width of the second hole 122 may be greater than the upper width of the first contact structure 112. In this case, the interconnection structure shown in FIG. 2 or FIG. 4 may be formed by subsequent processes.

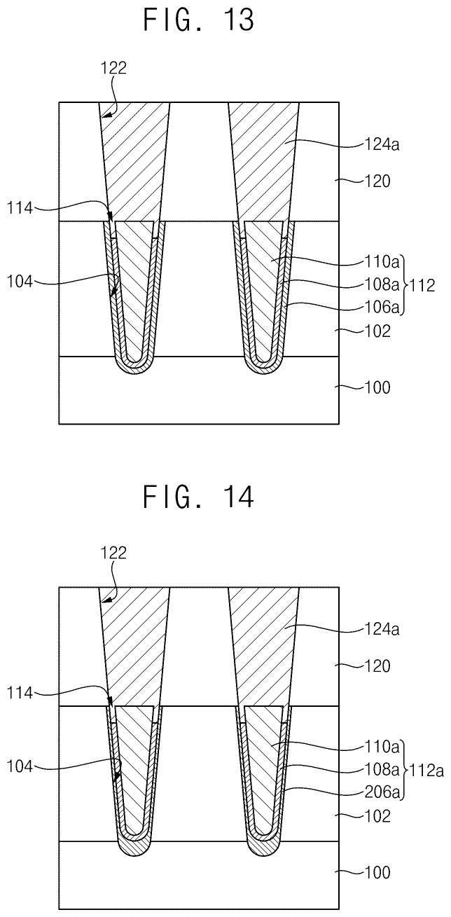

Referring to FIG. 12, a second metal layer 124 may be formed on the second insulating interlayer 120 and the first contact structure 112 to fill the second hole 122.

In example embodiments, the second metal layer 124 may completely fill the recess 114 of the bottom of the second hole 122.

In example embodiments, the second metal layer 124 may be formed by a selective chemical vapor deposition process in which a layer may be selectively deposited from the bottom of the second hole 122. The second metal layer 124 may be formed by a bottom-up fill growth process. In a case of the bottom-up fill growth process, a growth rate of the layer on the upper surfaces of the first metal pattern 110a and the seed metal layer pattern 108a exposed by the bottom of the second hole may be higher than a growth rate of the layer on an upper surface of the second insulating interlayer. Accordingly, the layer may be grown in the vertical direction from the upper surfaces of the first metal pattern 110a and the seed metal layer pattern 108a exposed by the bottom of the second hole 122 to form the second metal layer. In this case, a metal may be grown along grains of the upper surfaces of the first metal pattern 110a and the seed metal layer pattern 108a, and thus the second metal layer 124 may have a single grain. Accordingly, the second metal layer 124 may fill the recess 114 and the second hole 122 without a void.

The process for forming the second metal layer 124 may include a chemical vapor deposition process or an atomic layer deposition process. In example embodiments, the second metal layer 124 may include tungsten. However, the second metal layer 124 may not be limited to tungsten. For example, the second metal layer 124 may include aluminum, copper, ruthenium, cobalt, nickel, palladium, platinum, silver, gold, etc.

After performing the deposition process, an annealing process may be further performed. A void or a seam included in the second metal layer 124 may be removed by the annealing process.

As described above, a barrier layer may not be formed on the surface of the second hole 122 before forming the second metal layer 124. When a conductive pattern (e.g., the first metal pattern 110a and the seed metal layer pattern 108a) contacting a lower surface of the second metal layer 124 includes metal, the barrier layer may not be formed under the second metal layer 124 for a low resistance of the interconnection structure.

The second metal layer 124 may directly contact the upper sidewall and the upper surface of the first metal pattern 110a exposed by the bottom of the second hole 122, the uppermost surface of the seed metal layer pattern 108a, and the upper sidewall of the barrier pattern 106a.

Referring to FIG. 13, the second metal layer 124 may be planarized until the upper surface of the second insulating interlayer 120 is exposed to form a second metal pattern 124a in the second hole 122. The planarization process may include a chemical mechanical polishing process or an etch-back process.

A shape of the second metal pattern 124a may be determined by a shape of the second hole 122. In example embodiments, the second metal pattern 124a may be a via contact contacting a metal thereunder. In some example embodiments, the second metal pattern 124a may be a conductive line pattern.

A lower portion of the second metal pattern 124a may directly contact the upper sidewall and an entire of upper surface of the first metal pattern 110a. Additionally, the lower portion of the second metal pattern 124a may directly contact the uppermost surface of the seed metal layer pattern 108a and the sidewall of the barrier pattern 106a.

A contact area between the second metal pattern 124a and the first metal pattern 110a having low resistance may be increased. Accordingly, the resistance of the interconnection structure including the first contact structure 112 and the second metal pattern 124a may be decreased.

Hereinafter, interconnection structures having various shapes may be described.

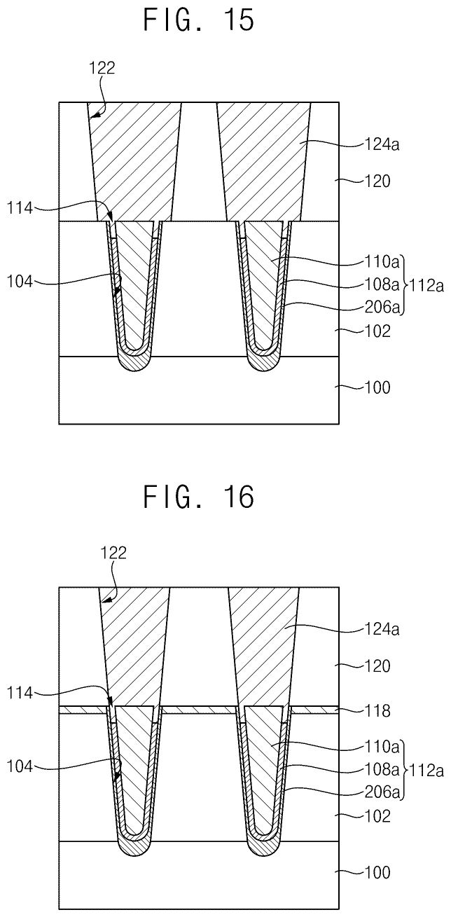

FIG. 14 is a cross-sectional view illustrating an interconnection structure according to an example embodiment. FIG. 15 is a cross-sectional view illustrating an interconnection structure according to an example embodiment.

The interconnection structure shown in FIG. 14 may be substantially the same as the interconnection structure shown in FIG. 1, except for a shape of the first contact structure. The interconnection structure shown in FIG. 15 may be substantially the same as the interconnection structure shown in FIG. 2, except for a shape of the first contact structure. Therefore, redundant descriptions may be omitted.

Referring to FIG. 14, the first contact structure 112a may pass through the first insulating interlayer 102 on the substrate 100. The first contact structure 112a may include the barrier pattern 206a, the seed metal layer pattern 108a, and the first metal pattern 110a.

The barrier pattern 206a may be formed on a sidewall and a bottom of the first hole 104. The barrier pattern 206a on the sidewall of the first hole 104 may have a thickness different from a thickness of the on the barrier pattern 206a on a bottom of the first hole 104. In example embodiments, the thickness of the barrier pattern 206a on the sidewall of the first hole 104 may be less than the thickness of the barrier pattern 206a on the bottom of the first hole 104. The barrier pattern 206a may include, e.g., titanium, titanium nitride, tantalum, tantalum nitride, tungsten nitride, tungsten, etc.

The seed metal layer pattern 108a may be formed on the barrier pattern 206a, and may be conformally formed on the sidewall and the bottom of the first hole 104. The seed metal layer pattern 108a may have a uniform thickness.

The first metal pattern 110a may be formed on the seed metal layer pattern 108a to fill the first hole 104. The seed metal layer pattern 108a and the first metal pattern 110a may include the same metal.

The seed metal layer pattern 108a and the first metal pattern 110a may be the same as those described with reference to FIG. 1. Accordingly, the first contact structure 112a may have the recess 114 disposed between the barrier pattern 206a and the first metal pattern 110a above the seed metal layer pattern 108a.

The second insulating interlayer 120 may be on the first contact structure 112a and the first insulating interlayer 102. The second metal pattern 124a may pass through the second insulating interlayer 120, and may contact the first contact structure 112a.

In example embodiments, as shown in FIG. 14, a width of the lower surface of the second metal pattern 124a may be substantially the same as or less than an upper width of the first contact structure 112a.

In some example embodiments, as shown in FIG. 15, the width of the lower surface of the second metal pattern 124a may be greater than the upper width of the first contact structure 112a. The interconnection structure shown in FIG. 15 may be the same as the interconnection structure shown in FIG. 14, except for the width of the lower surface of the second metal pattern 124a.

A contact area between the second metal pattern 124a and the first metal pattern 110a having low resistance may be increased. Accordingly, a resistance of the interconnection structure including the first contact structure 112a and the second metal pattern 124a may be decreased.

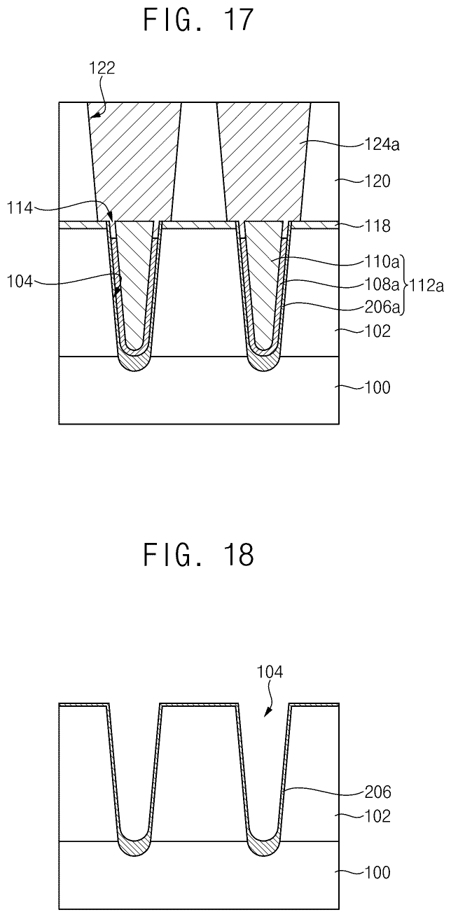

FIG. 16 is a cross-sectional view illustrating an interconnection structure according to an example embodiment. FIG. 17 is a cross-sectional view illustrating an interconnection structure according to an example embodiment.

The interconnection structure shown in FIG. 16 may be substantially the same as the interconnection structure shown in FIG. 3, except for a shape of the first contact structure. The interconnection structure shown in FIG. 17 may be substantially the same as an interconnection structure shown in FIG. 4, except for a shape of the first contact structure.

Referring to FIG. 16, the first insulating interlayer 102 and an etch stop layer 118 may be sequentially stacked on the substrate 100. The first contact structure 112a may pass through the first insulating interlayer 102 and the etch stop layer 118. The first contact structure 112a may be the same as that described with reference to FIG. 14.

An uppermost surface of the seed metal layer pattern 108a included in the first contact structure 112a may not be coplanar with uppermost surfaces of the barrier pattern 206a and the first metal pattern 110a. The uppermost surfaces of the barrier pattern 206a and the first metal pattern 110a may be coplanar with the upper surface of the etch stop layer 118.

In the first contact structure 112a, the uppermost surface of the seed metal layer pattern 108a may be lower than the uppermost surfaces of the barrier pattern 206a and the first metal pattern 110a. A recess 114 may be disposed between the barrier pattern 206a and the first metal pattern 110a above the seed metal layer pattern 108a.

The second insulating interlayer 120 may be on the first contact structure 112a and the etch stop layer 118. The second metal pattern 124a may pass through the second insulating interlayer 120, and may contact the first contact structure 112a.

In example embodiments, as shown in FIG. 16, a width of the lower surface of the second metal pattern 124a may be substantially the same as or less than an upper width of the first contact structure 112a.

In some example embodiments, as shown in FIG. 17, the width of the lower surface of the second metal pattern 124a may be greater than the upper width of the first contact structure 112a. The interconnection structure shown in FIG. 17 may be the same as the interconnection structure shown in FIG. 16, except for the width of the lower surface of the second metal pattern 124a.

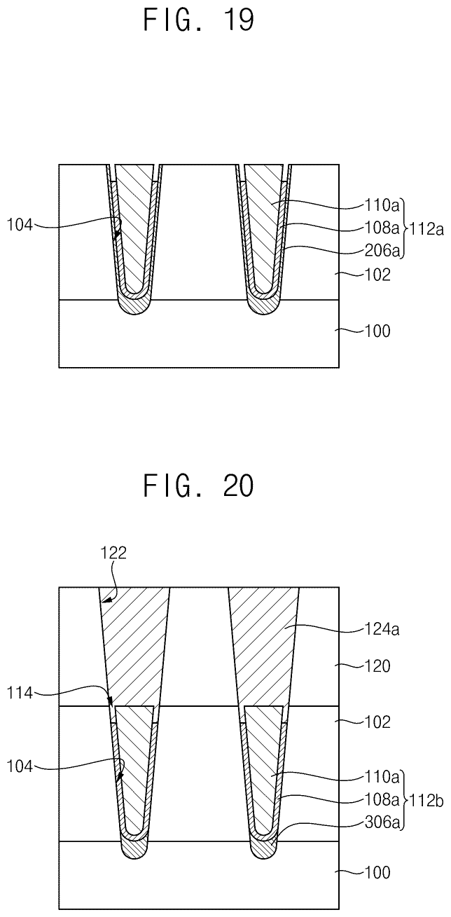

FIGS. 18 and 19 are cross-sectional views illustrating a method for manufacturing an interconnection structure according to an example embodiment.

The method for manufacturing the interconnection structure may be substantially the same as those described with reference to FIGS. 5 to 13, except for a deposition process of the barrier layer.

Referring to FIG. 18, first, the process described with reference to FIG. 5 may be performed.

A barrier layer 206 may be formed on a sidewall and a bottom of the first holes 104 and an upper surface of the first insulating interlayer 102. The barrier layer 206 may be formed to have different thicknesses on sidewalls of the first holes, on bottoms of the first holes and on the upper surface of the first insulating interlayer 102. In example embodiments, the barrier layer 206 on sidewalls the first holes may have the thickness less than the thickness of the barrier layer 206 on the bottoms of the first holes. The barrier layer 206 may be formed by, e.g., a physical vapor deposition process.

Referring to FIG. 19, the first contact structure 112a may be formed on the barrier layer 206 by performing the same processes described with reference to FIGS. 7 to 9.

Thereafter, the processes described with reference to FIGS. 10 to 13 may be performed to form the interconnection structure shown in FIG. 14.

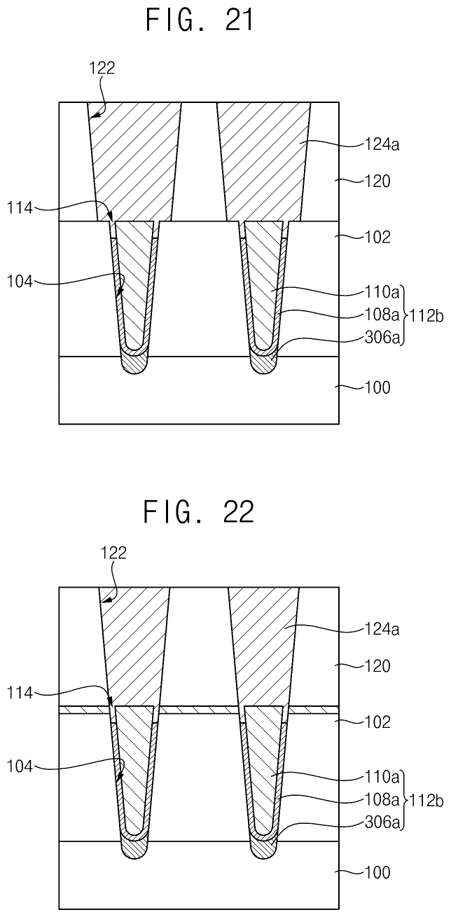

FIG. 20 is a cross-sectional view illustrating an interconnection structure according to an example embodiment. FIG. 21 is a cross-sectional view illustrating an interconnection structure according to an example embodiment.

The interconnection structure shown in FIG. 20 may be substantially the same as the interconnection structure shown in FIG. 1, except for a shape of the first contact structure. The interconnection structure shown in FIG. 21 may be substantially the same as the interconnection structure shown in FIG. 2, except for a shape of the first contact structure. Therefore, redundant descriptions may be omitted.

Referring to FIG. 20, a first contact structure 112b may pass through the first insulating interlayer 102 on the substrate 100. The first contact structure 112b may include a barrier pattern 306a, the seed metal layer pattern 108a, and the first metal pattern 110a.

The barrier pattern 306a may be formed only on a bottom of the first hole 104. The barrier pattern 306a may not be formed on a sidewall of the first hole 104. The barrier pattern 306a may include, e.g., titanium, titanium nitride, tantalum, tantalum nitride, tungsten nitride, tungsten, etc.

The seed metal layer pattern 108a may be formed on the barrier pattern 306a and the first insulating interlayer 102 exposed by the sidewall of the first hole 104. The seed metal layer pattern 108a may be formed conformally along the sidewall and bottom of the first hole 104.

The first metal pattern 110a may be formed on the seed metal layer pattern 108a to fill the first hole 104. The seed metal layer pattern 108a and the first metal pattern 110a may include the same metal.

The seed metal layer pattern 108a and the first metal pattern 110a may be the same as those described with reference to FIG. 1, respectively.

The second insulating interlayer 120 may be on the first contact structure 112b. The second metal pattern 124a may pass through the second insulating interlayer 120, and may contact the first contact structure 112b.

In example embodiments, as shown in FIG. 20, a width of the lower surface of the second metal pattern 124a may be substantially the same as or less than an upper width of the first contact structure 112b.

In some example embodiments, as shown in FIG. 21, the width of the lower surface of the second metal pattern 124a may be greater than the upper width of the first contact structure 112b. The interconnection structure shown in FIG. 21 may be substantially the same as the interconnection structure shown in FIG. 20, except for the width of the lower surface of the second metal pattern 124a.

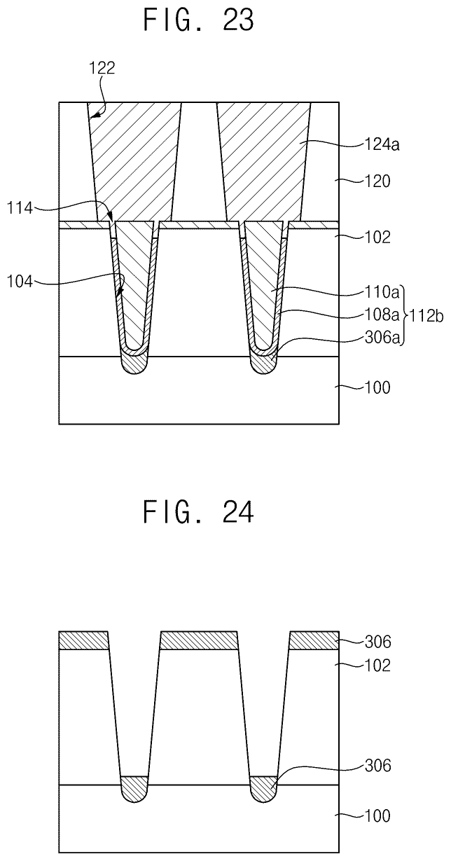

FIG. 22 is a cross-sectional view illustrating an interconnection structure according to an example embodiment. FIG. 23 is a cross-sectional view illustrating an interconnection structure according to an example embodiment.

The interconnection structure shown in FIG. 22 may be substantially the same as the interconnection structure shown in FIG. 3, except for a shape of the first contact structure. The interconnection structure shown in FIG. 23 may be substantially the same as the interconnection structure shown in FIG. 4, except for a shape of the first contact structure.

Referring to FIG. 22, the first insulating interlayer 102 and the etch stop layer 118 may be sequentially stacked on the substrate 100. The first contact structure 112b may pass through the first insulating interlayer 102 and the etch stop layer 118. The first contact structure 112b may be the same as that described with reference to FIG. 20.

The second insulating interlayer 120 may be on the first contact structure 112b and the etch stop layer 118. The second metal pattern 124a may pass through the second insulating interlayer 120, and may contact the first contact structure 112b.

In example embodiments, as shown in FIG. 22, a width of the lower surface of the second metal pattern 124a may be substantially the same as or less than an upper width of the first contact structure 112b.

In some example embodiments, as shown in FIG. 23, the width of the lower surface of the second metal pattern 124a may be greater than the upper width of the first contact structure 112b. The interconnection structure shown in FIG. 23 may be the same as the interconnection structure shown in FIG. 22, except for the width of the lower surface of the second metal pattern 124a.

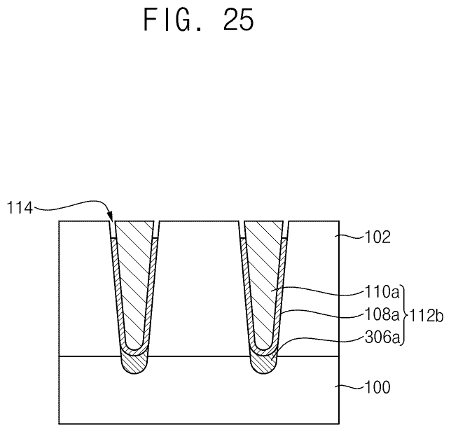

FIGS. 24 and 25 are cross-sectional views illustrating a method for manufacturing an interconnection structure according to an example embodiment.

Referring to FIG. 24, first, the processes described with reference to FIG. 5 may be performed.

A barrier layer 306 may be formed on a bottom of the first holes 104 and an upper surface of the first insulating interlayer 102. The barrier layer 306 may not be formed on sidewalls of the first holes 104. The barrier layer 306 may be formed by, e.g., a physical vapor deposition process.

Referring to FIG. 25, the first contact structure 112b may be formed on the barrier layer 306 by performing the same processes described with reference to FIGS. 7 to 9.

Thereafter, the processes described with reference to FIGS. 10 to 13 may be performed to form the interconnection structure shown in FIG. 20.

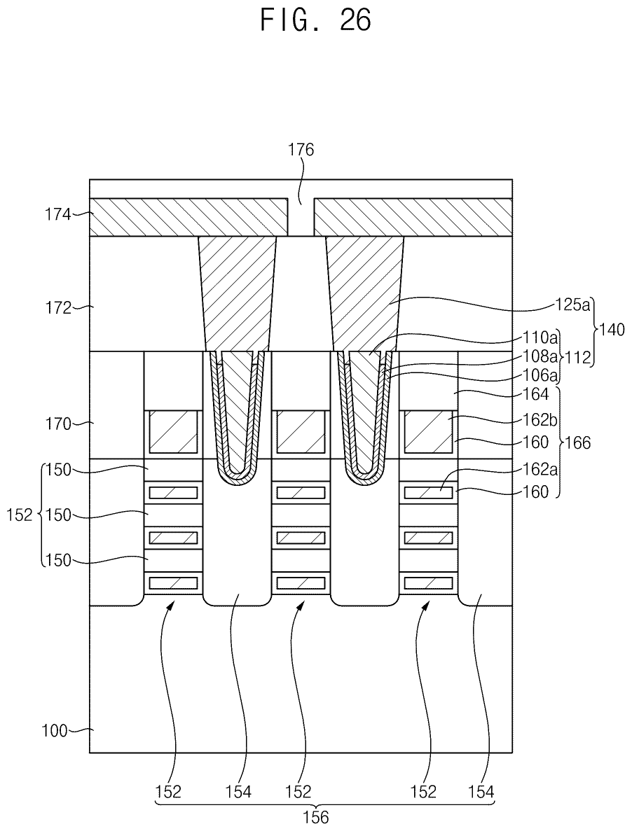

FIG. 26 is a cross-sectional view illustrating a semiconductor device including an interconnection structure according to an example embodiment.

FIG. 26 may be a semiconductor device including an MBC-FET.

Referring to FIG. 26, the semiconductor device may include a nanosheet structure 156, a gate structure 166 and an interconnection structure 140 on a substrate 100.

Upper portions of the substrate 100 may serve as lower active patterns. A device isolation pattern (not shown) may be disposed between the lower active patterns.

The nanosheet structure 156 may be on the lower active pattern.

The nanosheet structure 156 may include a semiconductor pattern 154 and nanosheet stacks 152. The semiconductor pattern 154 may be disposed between the nanosheet stacks 152. The nanosheet structure 156 may have a structure in which the semiconductor patterns 154 and the nanosheet stacks 152 are alternately arranged in a first direction parallel to an upper surface of the substrate 100 and are connected to each other.

Each of the nanosheet stacks 152 may have a structure in which silicon patterns 150 are spaced apart in a vertical direction perpendicular to the upper surface of the substrate 100. A first gap may be disposed between the silicon patterns 150 in the vertical direction.

A gate structure 166 may be disposed to cover the surface of the nanosheet stack 152. The gate structure 166 may fill the first gap, and may extend in a second direction perpendicular to the first direction and parallel to the upper surface of the substrate 100. An upper surface of the gate structure 166 may be substantially flat, and may be higher than an uppermost surface of the nanosheet stack 152.

The gate structure 166 may include a gate insulation layer 160, a lower gate electrode 162a, an upper gate electrode 162b, and a capping pattern 164.

The lower gate electrode 162a may be disposed below the uppermost surface of the nanosheet stack 152 and inside the first gap. The upper gate electrode 162b may be disposed on the uppermost surface of the nanosheet stack 152. The capping pattern 164 may be disposed on the upper gate electrode 162b. The lower gate electrode 162a and the upper gate electrode 162b may include a metal. The lower gate electrode 162a and the upper gate electrode 162b may include, e.g., tungsten.

The semiconductor pattern 154 may include, e.g., silicon or silicon germanium. The semiconductor pattern 154 may be doped with N-type or P-type impurities.

The nanosheet structure 156 and the gate structure 166 may be provided as MBC-FET.

A first insulating interlayer 170 may be on the semiconductor pattern 154 to fill a space between the gate structures 166. In example embodiments, the first insulating interlayer 170 may include silicon nitride.

A first contact structure 112 may pass through the first insulating interlayer 170, and may contact the upper surface of the semiconductor pattern 154. The first contact structure 112 may include a barrier pattern 106a, a seed metal layer pattern 108a, and a first metal pattern 110a.

The barrier pattern 106a may surround an outer surface of the seed metal layer pattern 108a. The seed metal layer pattern 108a may be conformally on the sidewall and the bottom of the first hole 104 in the first insulating interlayer 170. The seed metal layer pattern 108a may have a first resistance. The first metal pattern 110a may be on the seed metal layer pattern 108a to fill the first hole 104. An upper sidewall of the first metal pattern 110a may be exposed above an uppermost surface of the seed metal layer pattern 108a. The first metal pattern 110a may have a second resistance lower than the first resistance. An upper surface of the first metal pattern 110a may be coplanar with the upper surface of the first insulating interlayer 170. The uppermost surface of the seed metal layer pattern 108a may be lower than the upper surface of the first insulating interlayer 170.

As shown in FIG. 26, the first contact structure 112 may have the same structure as that described with reference to FIG. 1. In some example embodiments, the first contact structure may have the same structure as that described with reference to FIG. 14 or FIG. 20.

In the first contact structure 112, the recess 114 may be disposed between the barrier pattern 106a and the first metal pattern 110a above the seed metal layer pattern 108a.

A second insulating interlayer 172 may be on the first insulating interlayer 170 and the first contact structure 112. The second insulating interlayer 172 may include, e.g., silicon oxide.

In example embodiments, an etch stop layer (not shown) may be further included between the first insulating interlayer 170 and the second insulating interlayer 172.

A via contact 125a may pass through the second insulating interlayer 172, and may contact the first contact structure 112.

The via contact 125a may be substantially the same as the second metal pattern 124a described with reference to FIG. 1.

The via contact 125a may directly contact the upper sidewall and an entire of upper surface of the first metal pattern 110a. Additionally, the via contact 125a may directly contact the uppermost surface of the seed metal layer pattern 108a and the sidewall of the barrier pattern 106a.

A contact area between the via contact 125a and the first metal pattern 110a having low resistance may be increased. Accordingly, a resistance of the interconnection structure 140 including the first contact structure 112 and the via contact 125a may be decreased.

A wiring line 174 contacting the via contact 125a may be on the via contact 125a and the second insulating interlayer 172. A third insulating interlayer 176 may be on the wiring line and the second insulating interlayer 172 to cover the wiring line 174 and the second insulating interlayer 172. The third insulating interlayer 176 may include, e.g., silicon oxide or silicon nitride.

The interconnection structure 140 may have low resistance. Accordingly, a semiconductor device including the interconnection structure 140 may have high performance.

The foregoing is illustrative of various example embodiments and is not to be construed as limiting thereof. Although a few example embodiments have been described, those skilled in the art will readily appreciate that many modifications are possible in the example embodiments without materially departing from the novel teachings and advantages of inventive concepts.

What is claimed is:

1. An interconnection structure in a semiconductor device, comprising:
a substrate;
a first insulating interlayer on the substrate;
a first metal pattern on the substrate and passing through the first insulating interlayer;
a seed metal layer pattern surrounding a portion of a sidewall of the first metal pattern, a bottom of the first metal pattern, an upper sidewall of the first metal pattern and an upper surface of the first metal pattern, the upper sidewall of the first metal pattern and the upper surface of the first metal pattern being exposed by the seed metal layer pattern; and
a second metal pattern directly contacting an uppermost surface of the seed metal layer pattern, the upper sidewall of the first metal pattern, and the upper surface of the first metal pattern, the second metal pattern filling at least a recess between the first insulating interlayer and the first metal pattern.

2. The interconnection structure in the semiconductor device of claim 1, wherein a resistance of the first metal pattern is lower than a resistance of the seed metal layer pattern.

3. The interconnection structure in the semiconductor device of claim 1, wherein the second metal pattern has a single grain.

4. The interconnection structure in the semiconductor device of claim 1, further comprising:
a barrier pattern between a bottom of the seed metal layer pattern and a surface of the substrate.

5. The interconnection structure in the semiconductor device of claim 4, wherein the barrier pattern surrounds an outer surface of the seed metal layer pattern.

6. The interconnection structure in the semiconductor device of claim 1, wherein the seed metal layer pattern and the first metal pattern include a same metal.

7. The interconnection structure in the semiconductor device of claim 1, wherein
the seed metal layer pattern includes tungsten including boron or tungsten including boron and silicon, and
the first metal pattern includes bulk tungsten.

8. The interconnection structure in the semiconductor device of claim 1, wherein
the upper surface of the first metal pattern is coplanar with an upper surface of the first insulating interlayer, and
the uppermost surface of the seed metal layer pattern is lower than the upper surface of the first metal pattern.

9. The interconnection structure in the semiconductor device of claim 1, further comprising:
a second insulating interlayer on the first insulating interlayer, wherein
the second metal pattern passes through the second insulating interlayer.

10. An interconnection structure in a semiconductor device, comprising:
a substrate;
a first insulating interlayer on the substrate, and the first insulating interlayer including a first hole exposing a surface of the substrate;
a seed metal layer pattern conformally on a sidewall of the first hole and a bottom of the first hole, the seed metal layer pattern having a first resistance;
a first metal pattern on the seed metal layer pattern and filling the first hole, an upper sidewall of the first metal pattern positioned above an uppermost surface of the seed metal layer pattern, the first metal pattern being exposed by the seed metal layer, the first metal pattern having a second resistance, and the second resistance being lower than the first resistance;
a second insulating interlayer on the first insulating interlayer; and
a second metal pattern passing through the second insulating interlayer,
the second metal pattern directly contacting the uppermost surface of the seed metal layer pattern, the upper sidewall of the first metal pattern, and an upper surface of the first metal pattern.

11. The interconnection structure in the semiconductor device of claim 10, further comprising:
a barrier pattern between a bottom of the seed metal layer pattern and the surface of the substrate.

12. The interconnection structure in the semiconductor device of claim 10, wherein
the seed metal layer pattern includes tungsten including boron or tungsten including boron and silicon, and
the first metal pattern includes bulk tungsten.

13. The interconnection structure in the semiconductor device of claim 10, wherein the second metal pattern has a single grain.

14. The interconnection structure in the semiconductor device of claim 10, wherein
the upper surface of the first metal pattern is coplanar with an upper surface of the first insulating interlayer, and
the uppermost surface of the seed metal layer pattern is lower than the upper surface of the first metal pattern.

15. The interconnection structure in the semiconductor device of claim 10, wherein
the first insulating interlayer and the second insulating interlayer include different insulating materials, and
the first insulating interlayer has an etch selectivity with respect to the second insulating interlayer.

16. The interconnection structure in the semiconductor device of claim 10, further comprising:
an etch stop layer between the first insulating interlayer and the second insulating interlayer.

17. A semiconductor device comprising:
a substrate;
a nanosheet structure on the substrate, the nanosheet structure including a nanosheet stack and a semiconductor pattern on sidewalls of the nanosheet stack, and the nanosheet stack including silicon patterns spaced apart in a vertical direction, the vertical direction being perpendicular to a surface of the substrate;
a gate structure on the nanosheet stack, the gate structure covering the nanosheet stack;
a first insulating interlayer covering sidewalls of the gate structure and on the semiconductor pattern, the first insulating interlayer including a first hole exposing the semiconductor pattern;
a seed metal layer pattern conformally on a sidewall of the first hole and a bottom of the first hole, the seed metal layer pattern having a first resistance;
a first metal pattern on the seed metal layer pattern and filling the first hole, an upper sidewall of the first metal pattern positioned above an uppermost surface of the seed metal layer pattern, the uppermost surface of the seed metal layer pattern being exposed by the seed metal layer pattern, the first metal pattern having a second resistance, and the second resistance being lower than the first resistance;
a second insulating interlayer on the first insulating interlayer;
a second metal pattern passing through the second insulating interlayer,
the second metal pattern directly contacting the uppermost surface of the seed metal layer pattern, the upper sidewall of the first metal pattern, and an upper surface of the first metal pattern.

18. The semiconductor device of claim 17, wherein the second metal pattern has a single grain.

19. The semiconductor device of claim 17, further comprising:
a barrier pattern surrounding an outer surface of the seed metal layer pattern.

20. The semiconductor device of claim 17, wherein
the upper surface of the first metal pattern is coplanar with an upper surface of the first insulating interlayer, and
the uppermost surface of the seed metal layer pattern is lower than the upper surface of the first metal pattern.
